(19) United States
(12) Patent Application Publication
(10) Pub. No.: US 2020/0294598 A1
(43) Pub. Date: Sep. 17, 2020

(54) Routing Bad Block Flag for Reducing Routing Signals

(71) Applicant: SanDisk Technologies LLC, Addison, TX (US)

(72) Inventors: Kenneth Louie, Sunnyvale, CA (US); Seok Tae Kim, San Jose, CA (US); Arka Ganguly, Scotts Valley, CA (US); Qui Nguyen, San Jose, CA (US)

(21) Appl. No.: 16/352,824

(22) Filed: Mar. 14, 2019

(51) Int. Cl. G11C 16/08; G11C 16/04

(52) U.S. Cl. CPC G11C 16/08; G11C 11/5621; G11C 16/0483

(57) ABSTRACT

Apparatuses, systems, methods, and computer program products are disclosed for reducing routing signals. An apparatus includes a first block decoder circuit that senses bad block data of a first latch circuit corresponding to a first memory block and couple the bad block data onto a bus. An apparatus includes a comparator circuit that compares the bad block data against a reference, sets a bad block flag, and routes the bad block flag on a routing line across an array of storage elements. An apparatus includes a second block decoder circuit that receives the bad block flag from the routing line, determines a condition of the first memory block based on the bad block flag, and determines a generation of a block selection signal for selecting a second memory block.

### TECHNICAL FIELD

The present disclosure pertains generally to routing signals for operation of memory devices, and more specifically to reducing the number of routing signals for the operation of memory devices.

### BACKGROUND

Many electrical circuits and devices, such as memory devices or the like, use routing lines. Routing lines may be used to carry signals and/or voltages from one physical location to another physical location in memory devices, for example. However, various challenges are present in operating such memory devices. For example, there may be a limited amount of space in memory devices for routing lines. As a result, there may be issues in memory devices caused by the congestion of routing lines, such as voltage coupling with neighboring routing lines and degraded performance.

It would be desirable to address at least this issue.

### SUMMARY

Apparatuses, methods, systems, and other aspects are presented for reducing the number of routing signals in a memory device for performing operations.

One innovative aspect includes an apparatus comprising: a first block decoder circuit and a comparator circuit. The first block decoder circuit is configured to determine first latch data of a first latch circuit and read out the first latch data onto a bus, the first latch circuit storing the first latch data indicating a condition of a first memory block. The comparator circuit is configured to receive the first latch data from the bus, set a block flag based on the first latch data and send the block flag on a routing line to a second block decoder circuit.

Some implementations may optionally include one or more of the following features: that the apparatus further comprises the second block decoder circuit that is configured to receive the block flag from the routing line and determine whether the block flag indicates that the first memory block is defective; that the second block decoder circuit is configured to inhibit an activation of a block selection signal for selecting a second memory block responsive to the block flag indicating that the first memory block is defective; that the second block decoder circuit is configured to allow an activation of a block selection signal for selecting a second memory block responsive to the block flag indicating that the first memory block is non-defective; that the second block decoder circuit is configured to determine second latch data of a second latch circuit, the second latch circuit storing the second latch data indicating a condition of a second memory block; that the first block decoder circuit and the second block decoder circuit are on opposite sides of an array of memory elements; that the first memory block and the second memory block comprise a unit of memory blocks; that the first block decoder circuit and the second block decoder circuit determine an activation of a block selection signal shared by the unit of memory block; that a plurality of transfer circuits are on opposite sides of an array of memory elements configured to receive the block selection signal; and that the routing line carrying the block flag is an upper metal layer.

Another general aspect includes a system comprising: a control circuit coupled to an array of storage elements. The control circuit comprises: a first block decoder circuit that is configured to sense bad block data of a first latch circuit corresponding to a first memory block and couple the bad block data onto a bus, a comparator circuit that is configured to compare a value of the bad block data from the bus against a reference value, set a bad block flag based on the comparison and route the bad block flag on a routing line across the array of storage elements, and a second block decoder circuit that is configured to receive the bad block flag from the routing line, determine a condition of the first memory block based on the bad block flag and determine a generation of a block selection signal for selecting a second memory block based on the condition of the first memory block.

Some implementations may optionally include one or more of the following features: that the comparator circuit is configured to set the bad block flag to a logic low value if the value of the bad block data is greater than the reference value; that the second block decoder circuit is configured to determine that the condition of the first memory block is good in response to the logic low value of the bad block flag and allow the generation of the block selection signal for selecting the second memory block; that the shift circuit is configured to increase a voltage of the block selection signal to generate a gate voltage for a transfer circuit associated with the second memory block; that the comparator circuit is configured to set the bad block flag to a logic high value if the value of the bad block data is less than the reference value; and that the second block decoder circuit is configured to determine that the condition of the first memory block is bad in response to the logic high value of the bad block flag and inhibit the generation of the block selection signal for selecting the second memory block.

Another general aspect includes an apparatus comprising: a control circuit placed under an array of storage elements. The control circuit comprises: a first block decoder circuit, at a first end of the array of storage elements, that is configured to sense a voltage of bad block data stored by a first latch circuit for a first memory block and transfer the sensed voltage onto a bus, a comparator circuit that is configured to compare the sensed voltage against a reference voltage, set a bad block flag based on the comparison, and transmit the bad block flag to a second block decoder circuit on a routing line extending between the first block decoder circuit and the second block decoder circuit, and the second block decoder circuit, at a second end of the array of storage elements opposite to the first end, that is configured to determine whether the bad block flag indicates that the first memory block is operational and generate a block selection signal for selecting a second memory block responsive to the bad block indicating that the first memory block is operational.

Some implementations may optionally include one or more of the following features: that the second block decoder circuit is configured to inhibit generating the block selection signal responsive to the bad block flag indicating the first memory block is non-operational, that an inverter circuit is configured to invert a polarity of the block selection signal to generate an inverse polarity block selection signal, that a shift circuit is configured to increase a voltage of the block selection signal to generate a gate voltage for a transfer circuit associated with the second memory block, and that the voltage of the routing line transferring the bad block flag is about 2 volts and the gate voltage is about 30 volts.

Note that the above list of features is not all-inclusive, and many additional features and advantages are contemplated and fall within the scope of the present disclosure. Moreover, the language used in the present disclosure has been principally selected for readability and instructional purposes, and not to limit the scope of the subject matter disclosed herein.

### BRIEF DESCRIPTION OF THE DRAWINGS

FIG. 1A is an example block diagram illustrating one embodiment of a system for reducing routing lines.

FIG. 1B depicts an example block diagram of an example memory device.

FIG. 2 depicts an example block diagram illustrating one embodiment of a string of storage elements.

FIG. 3 depicts an example circuit of an array of memory cells.

FIG. 4 depicts one embodiment of a 3D, vertical NAND flash memory structure.

FIG. 5 depicts a schematic block diagram illustrating one embodiment of a routing reduction component.

FIG. 6 depicts an example circuit 600 for providing voltages to a block of memory cells.

FIG. 7 depicts a schematic block diagram of a configuration 700 illustrating one embodiment for routing a bad block flag.

FIG. 8 depicts an example circuit diagram illustrating one embodiment of a circuit 800 for routing a bad block flag between block decoders on opposite sides of an array of memory cells.

FIG. 9 depicts a schematic block diagram illustrating a further embodiment of a system 900 for routing a bad block flag.

FIG. 10 depicts a flowchart of an example process for routing a bad block flag.

The Figures depict various embodiments for purposes of illustration only. It should be understood that alternative embodiments of the structures and methods illustrated herein may be employed without departing from the principles described herein.

### DETAILED DESCRIPTION

Innovative technology, including various aspects such as apparatuses, processes, methods, systems, etc., is described for reducing the number of routing signals in a memory device. In the following description, for purposes of explanation, numerous specific details are set forth to provide a thorough understanding of the various aspects of different example embodiments. Note that any particular example embodiment may in various cases be practiced without all of the specific details and/or with variations, permutations, and combinations of the various features and elements described herein.

As described in detail below, in some memory devices, the memory cells are joined to one another such as in NAND strings in a block or sub-block. Each NAND string includes a number of memory cells connected in series between one or more drain-side select gate transistors (SGD transistors), on a drain-side of the NAND string which is connected to a bit line, and one or more source-side select gate transistors (SGS transistors), on a source-side of the NAND string which is connected to a source line. Further, the memory cells can be arranged with a common control gate line (e.g., word line) which acts a control gate. A set of word lines extends from the source side of a block to the drain side of a block. Memory cells can be connected in other types of strings and in other ways as well.

In a 3D memory structure, the memory cells may be arranged in vertical memory strings in a stack, where the stack includes alternating conductive and dielectric layers. The conductive layers act as word lines which are connected to the memory cells. Each memory string may have the shape of a pillar which intersects with the word lines to form the memory cells. The memory cells can include data memory cells, which are eligible to store user data, and dummy or non-data memory cells which are ineligible to store user data. A dummy word line is connected to a dummy memory cell. One or more dummy memory cells may be provided at the drain and/or source ends of a string of memory cells to provide a gradual transition in the channel voltage gradient.

In a 3D memory structure, a set of memory strings may form an array of memory cells. Such an array of memory cells may be divided into a large number of blocks of memory cells. For example, a block may be a unit of memory or storage. That is, each block may contain the minimum number of memory cells that may be, for example, erased together. Each block is typically divided into a number of physical pages. A logical page is a unit of programming or reading that contains a number of bits equal to the number of memory cells in a physical page. In a memory that stores one bit per cell, one physical page stores one logical page of data. In memories that store two bits per cell, a physical page stores two logical pages. The number of logical pages stored in a physical page thus reflects the number of bits stored per memory cell. One or more logical pages of data may be stored in one row of memory cells.

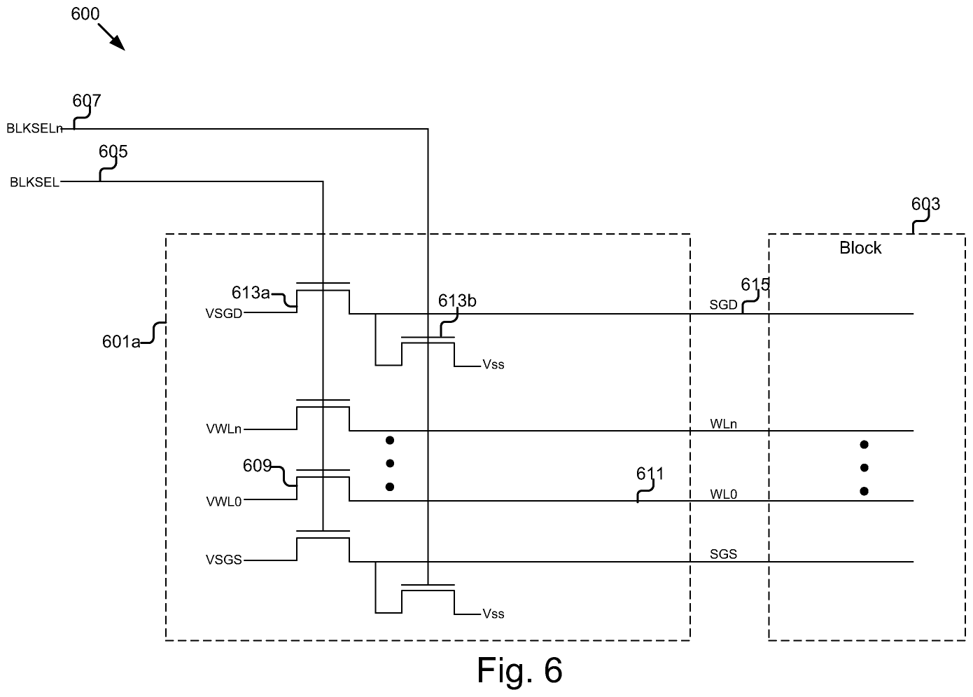

A memory operation, such as a read operation or an erase operation may involve selecting or unselecting one or more blocks of memory cells. For example, a block decoder determines and supplies block selection signals, such as BLKSEL and BLKSELn to a block to indicate whether the block is selected or unselected for a memory operation, as shown in FIG. 6.

Various approaches can be used to supply the block selection signals to the memory blocks. In previous approaches, each of the blocks were provided with a dedicated block decoder. However, this implementation takes up a lot of area. In one embodiment, a block decoder may be provided for every four blocks to save layout area in the memory device. As a result, every set of four blocks may share the same block selections signals. Block selection signals are supplied to the control gates of word line switch transistors (transfer circuit). Word line switch transistors control the supply of word line bias voltage to the word lines of a block for performing a memory operation.

Typically, the word line switch transistors are placed on opposite sides of the array of memory cells to drive the word lines of different blocks sharing the same block decoder and the block decoder that generates the block selection signals is placed on one side of the array of memory cells. This results in a large number of routing lines in an upper metal layer (e.g., M1 layer) spanning across the array of memory cells to carry block selection signals from the block decoders on one side to the corresponding blocks on the other side of the array of memory cells. Such a large number of routing lines for carrying block selection signals causes congestion and leads to less routing for other design blocks, such as sense amplifiers, YLOG, analog pumps, etc. in the memory device.

In some embodiments, some portion of the routing lines may carry low voltage signals and some other portion of the number of routing lines may carry high voltage signals. By way of example and not limitation, a high voltage line may comprise an M1 layer routing line carrying a BLKSEL signal (e.g., such as but not limited to a signal in a range between about 25 volts and about 30 volts), and a low voltage line may comprise an M1 layer routing line carrying a BLKSELn signal (e.g., such as but not limited to a signal in a range between about 2.5 volts and about 2.7 volts). As noted in the Background, these routing lines carrying block selection signals of different voltages across the array of memory cells may cause coupling to occur with other routing lines carrying other signals for operation in the memory device. By way of example, the M1 layer routing lines carrying the BLKSELn (e.g., about 2.7 volts) may couple up to M0 layer routing lines carrying the bit line voltage (e.g., about 25 volts) underneath the M1 layer routing lines during an erase operation. This may cause EDR violations in the low voltage transistors in the transfer circuit that are biased by BLKSELn. Additionally, BLKSEL is a high voltage signal (e.g., about 25 volts) and is routed on the M1 layer for a long distance across the array of memory cells. Such a long routing distance and heavy gate loading from word line switch transistors may make BLKSEL very slow, require a lot of power to charge up BLSKEL, and thereby increase pre-charge/discharge timings.

Techniques provided herein address the above and other issues. Various other features and benefits are described below.

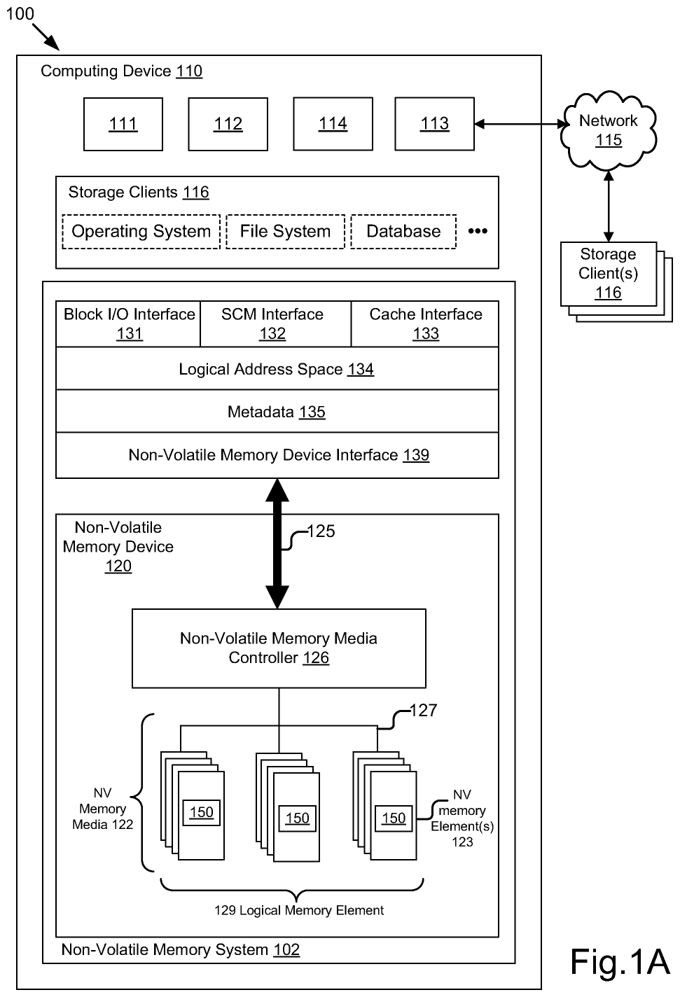

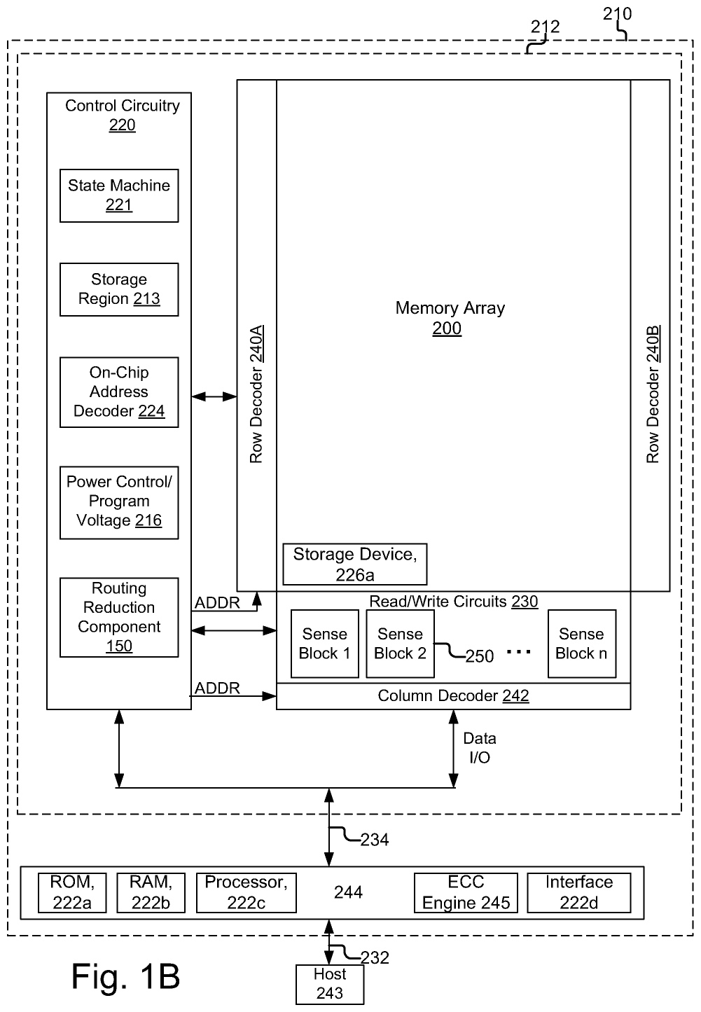

FIG. 1A is a block diagram of one embodiment of a system 100 comprising a routing reduction component 150 for a non-volatile memory device 120. The routing reduction component 150 may be part of and/or in communication with a non-volatile memory element 123, or the like. The routing reduction component 150 may operate on a non-volatile memory system 102 of a computing device 110, which may comprise a processor 111, volatile memory 112, and a communication interface 113. The processor 111 may comprise one or more central processing units, one or more general-purpose processors, one or more application-specific processors, one or more virtual processors (e.g., the computing device 110 may be a virtual machine operating within a host), one or more processor cores, or the like. The communication interface 113 may comprise one or more network interfaces configured to communicatively couple the computing device 110 and/or non-volatile memory controller 126 to a communication network 115, such as an Internet Protocol (IP) network, a Storage Area Network (SAN), a wireless network, a wired network, a combination of the foregoing, or the like.

The non-volatile memory device 120, in various embodiments, may be disposed in one or more different locations relative to the computing device 110. In one embodiment, the non-volatile memory device 120 comprises one or more non-volatile memory elements 123, such as semiconductor chips or packages or other integrated circuit devices disposed on one or more printed circuit boards, storage housings, and/or other mechanical and/or electrical support structures. For example, the non-volatile memory device 120 may comprise one or more direct inline memory module (DIMM) cards, one or more expansion cards and/or daughter cards, a solid-state-drive (SSD) or other hard drive devices, and/or may have another memory and/or storage form factor. The non-volatile memory device 120 may be integrated with and/or mounted on a motherboard of the computing device 110, installed in a port and/or slot of the computing device 110, installed on a different computing device 110 and/or a dedicated storage appliance on the network 115, in communication with the computing device 110 over an external bus (e.g., an external hard drive), or the like.

The non-volatile memory device 120, in one embodiment, may be disposed on a memory bus of a processor 111 (e.g., on the same memory bus as the volatile memory 112, on a different memory bus from the volatile memory 112, in place of the volatile memory 112, or the like). In a further embodiment, the non-volatile memory device 120 may be disposed on a peripheral bus of the computing device 110, such as a peripheral component interconnect express (PCI Express or PCIe) bus, a serial Advanced Technology Attachment (SATA) bus, a parallel Advanced Technology Attachment (PATA) bus, a small computer system interface (SCSI) bus, a FireWire bus, a Fibre Channel connection, a Universal Serial Bus (USB), a PCIe Advanced Switching (PCIe-AS) bus, or the like. In another embodiment, the non-volatile memory device 120 may be disposed on a data network 115, such as an Ethernet network, an Infiniband network, SCSI RDMA over a network 115, a storage area network (SAN), a local area network (LAN), a wide area network (WAN) such as the Internet, another wired and/or wireless network 115, or the like.

The computing device 110 may further comprise a non-transitory, computer-readable storage medium 114. The computer-readable storage medium 114 may comprise executable instructions configured to cause the computing device 110 (e.g., processor 111) to perform steps of one or more of the methods disclosed herein.

The non-volatile memory system 102, in the depicted embodiment, includes a routing reduction component 150. The routing reduction component 150, in one embodiment, is configured to sense bad block data within latch circuits holding information on the condition of a memory block, set a bad block flag based on the bad block data, route bad block flag across an array of memory elements on a routing line, and generate block selection signals for selecting or unselecting memory blocks. In some embodiments, the routing reduction component 150 includes two or more word line switches on opposite sides of an array of memory elements and used for coupling word line voltages to word lines for the non-volatile memory device 120 described below. The routing reduction component 150, in certain embodiments, may supply block select gate voltages (e.g., BLKSEL and BLKSELn) to two or more of the word line switches and select gate line switches. Thus, routing reduction may be performed.

In one embodiment, the routing reduction component 150 may comprise logic hardware of one or more non-volatile memory devices 120, such as a non-volatile memory media controller 126, a non-volatile memory element 123, a device controller, a field-programmable gate array (FPGA) or other programmable logic, firmware for an FPGA or other programmable logic, microcode for execution on a microcontroller, an application-specific integrated circuit (ASIC), or the like. In another embodiment, the routing reduction component 150 may comprise executable software code, such as a device driver or the like, stored on the computer-readable storage medium 114 for execution on the processor 111. In a further embodiment, the routing reduction component 150 may include a combination of both executable software code and logic hardware.

A device driver and/or the non-volatile memory media controller 126, in certain embodiments, may present a logical address space 134 to the storage clients 116. As used herein, a logical address space 134 refers to a logical representation of memory resources. The logical address space 134 may comprise a plurality (e.g., range) of logical addresses. As used herein, a logical address refers to any identifier for referencing a memory resource (e.g., data), including, but not limited to: a logical block address (LBA), cylinder/head/sector (CHS) address, a file name, an object identifier, an inode, a Universally Unique Identifier (UUID), a Globally Unique Identifier (GUID), a hash code, a signature, an index entry, a range, an extent, or the like.

A device driver for the non-volatile memory device 120 may maintain metadata 135, such as a logical to physical address mapping structure, to map logical addresses of the logical address space 134 to media storage locations on the non-volatile memory device(s) 120. A device driver may be configured to provide storage services to one or more storage clients 116. The storage clients 116 may include local storage clients 116 operating on the computing device 110 and/or remote, storage clients 116 accessible via the network 115 and/or network interface 113. The storage clients 116 may include, but are not limited to: operating systems, file systems, database applications, server applications, kernel-level processes, user-level processes, applications, and the like.

A device driver may be communicatively coupled to one or more non-volatile memory devices 120. The one or more non-volatile memory devices 120 may include different types of non-volatile memory devices including, but not limited to: solid-state storage devices, semiconductor storage devices, SAN storage resources, or the like. The one or more non-volatile memory devices 120 may comprise one or more respective non-volatile memory media controllers 126 and non-volatile memory media 122. A device driver may provide access to the one or more non-volatile memory devices 120 via a traditional block I/O interface 131. Additionally, a device driver may provide access to enhanced functionality through the SCM interface 132. The metadata 135 may be used to manage and/or track data operations performed through any of the Block I/O interface 131, SCM interface 132, cache interface 133, or other, related interfaces.

The cache interface 133 may expose cache-specific features accessible via a device driver for the non-volatile memory device 120. Also, in some embodiments, the SCM interface 132 presented to the storage clients 116 provides access to data transformations implemented by the one or more non-volatile memory devices 120 and/or the one or more non-volatile memory media controllers 126.

A device driver may present a logical address space 134 to the storage clients 116 through one or more interfaces. As discussed above, the logical address space 134 may comprise a plurality of logical addresses, each corresponding to respective media locations of the one or more non-volatile memory devices 120. A device driver may maintain metadata 135 comprising any-to-any mappings between logical addresses and media locations, or the like.

A device driver may further comprise and/or be in communication with a non-volatile memory device interface 139 configured to transfer data, commands, and/or queries to the one or more non-volatile memory devices 120 over a bus 125, which may include, but is not limited to: a memory bus of a processor 111, a peripheral component interconnect express (PCI Express or PCIe) bus, a serial Advanced Technology Attachment (ATA) bus, a parallel ATA bus, a small computer system interface (SCSI), FireWire, Fibre Channel, a Universal Serial Bus (USB), a PCIe Advanced Switching (PCIe-AS) bus, a network 115, Infiniband, SCSI RDMA, or the like. The non-volatile memory device interface 139 may communicate with the one or more non-volatile memory devices 120 using input-output control (IO-CTL) command(s), IO-CTL command extension(s), remote direct memory access, or the like.

The communication interface 113 may comprise one or more network interfaces configured to communicatively couple the computing device 110 and/or the non-volatile memory controller 126 to a network 115 and/or to one or more remote, network-accessible storage clients 116. The storage clients 116 may include local storage clients 116 operating on the computing device 110 and/or remote, storage clients 116 accessible via the network 115 and/or the network interface 113. The non-volatile memory controller 126 is part of and/or in communication with one or more non-volatile memory devices 120. Although FIG. 1A depicts a single non-volatile memory device 120, the disclosure is not limited in this regard and could be adapted to incorporate any number of non-volatile memory devices 120.

The non-volatile memory device 120 may comprise one or more elements 123 of non-volatile memory media 122, which may include but is not limited to: ReRAM, Memristor memory, programmable metallization cell memory, phase-change memory (PCM, PCME, PRAM, PCRAM, ovonic unified memory (OUM), chalcogenide RAM, or C-RAM), NAND flash memory (e.g., 2D NAND flash memory, 3D NAND flash memory), NOR flash memory, nano random access memory (nano RAM or NRAM), nanocrystal wire-based memory, silicon-oxide based sub-10 nanometer process memory, graphene memory, Silicon-Oxide-Nitride-Oxide-Silicon (SONOS), programmable metallization cell (PMC), conductive-bridging RAM (CBRAM), magneto-resistive RAM (MRAM), magnetic storage media (e.g., hard disk, tape), optical storage media, or the like. The one or more elements 123 of non-volatile memory media 122, in certain embodiments, comprise storage class memory (SCM).

While legacy technologies such as NAND flash may be block and/or page addressable, storage class memory, in one embodiment, is byte addressable. In further embodiments, storage class memory may be faster and/or have a longer life (e.g., endurance) than NAND flash; may have a lower cost, use less power, and/or have a higher storage density than DRAM; or offer one or more other benefits or improvements when compared to other technologies. For example, storage class memory may comprise one or more non-volatile memory elements 123 of ReRAM, Memristor memory, programmable metallization cell memory, phase-change memory, nano RAM, nanocrystal wire-based memory, silicon-oxide based sub-10 nanometer process memory, graphene memory, SONOS memory, PMC memory, CBRAM, MRAM, and/or variations thereof.

While the non-volatile memory media 122 is referred to herein as “memory media,” in various embodiments, the non-volatile memory media 122 may more generally comprise one or more non-volatile recording media capable of recording data, which may be referred to as a non-volatile memory medium, a non-volatile storage medium, or the like. Further, the non-volatile memory device 120, in various embodiments, may comprise a non-volatile recording device, a non-volatile memory device, a non-volatile storage device, or the like.

The non-volatile memory media 122 may comprise one or more non-volatile memory elements 123, which may include, but are not limited to: chips, packages, planes, die, or the like. A non-volatile memory media controller 126 may be configured to manage data operations on the non-volatile memory media 122 and may comprise one or more processors, programmable processors (e.g., FPGAs), ASICs, micro-controllers, or the like. In some embodiments, the non-volatile memory media controller 126 is configured to store data on and/or read data from the non-volatile memory media 122, to transfer data to/from the non-volatile memory device 120, and so on.

The non-volatile memory media controller 126 may be communicatively coupled to the non-volatile memory media 122 by way of a bus 127. The bus 127 may comprise an I/O bus for communicating data to/from the non-volatile memory elements 123. The bus 127 may further comprise a control bus for communicating addressing and other command and control information to the non-volatile memory elements 123. In some embodiments, the bus 127 may communicatively couple the non-volatile memory elements 123 to the non-volatile memory media controller 126 in parallel. This parallel access may allow the non-volatile memory elements 123 to be managed as a group, forming a logical memory element 129. The logical memory element may be partitioned into respective logical memory units (e.g., logical pages) and/or logical memory divisions (e.g., logical blocks). The logical memory units may be formed by logically combining physical memory units of each of the non-volatile memory elements.

The non-volatile memory controller 126 may organize a block of word lines within a non-volatile memory element 123, in certain embodiments, using addresses of the word lines, such that the word lines are logically organized into a monotonically increasing sequence (e.g., decoding and/or translating addresses for word lines into a monotonically increasing sequence, or the like). In a further embodiment, word lines of a block within a non-volatile memory element 123 may be physically arranged in a monotonically increasing sequence of word line addresses, with consecutively addressed word lines also being physically adjacent (e.g., WL0, WL1, WL2, WLN).

The non-volatile memory controller 126 may comprise and/or be in communication with a device driver executing on the computing device 110. A device driver may provide storage services to the storage clients 116 via one or more interfaces 131, 132, and/or 133. In some embodiments, a device driver provides a block-device I/O interface 131 through which storage clients 116 perform block-level I/O operations. Alternatively, or in addition, a device driver may provide a storage class memory (SCM) interface 132, which may provide other storage services to the storage clients 116. In some embodiments, the SCM interface 132 may comprise extensions to the block device interface 131 (e.g., storage clients 116 may access the SCM interface 132 through extensions or additions to the block device interface 131). Alternatively, or in addition, the SCM interface 132 may be provided as a separate API, service, and/or library. A device driver may be further configured to provide a cache interface 133 for caching data using the non-volatile memory system 102.

A device driver may further comprise a non-volatile memory device interface 139 that is configured to transfer data, commands, and/or queries to the non-volatile memory media controller 126 over a bus 125, as described above.

FIG. 1B is a block diagram of an example memory device. The memory device 210, such as a non-volatile storage system, may include one or more memory die 212. The memory die 212 includes a memory structure 200 of memory cells, such as an array of memory cells, control circuitry 220, and read/write circuits 230. In one embodiment, access to the memory structure 200 by the various peripheral circuits is implemented in a symmetric fashion, on opposite sides of the memory structure 200. The memory structure 200 is addressable by word lines via a row decoder 240A/240B and by bit lines via a column decoder 242. The read/write circuits 230 include multiple sense blocks 250 from 1, 2, . . . , n (sense circuit) and allow a page of memory cells to be read or programmed in parallel. Typically, a controller 244 is included in the same memory device 210 (e.g., a removable storage card) as the one or more memory die 212. The controller 244 may be separate from the memory die 212. Commands and data are transferred between the host 243 and controller 244 via a data bus 232, and between the controller 244 and the one or more memory die 212 via lines 234.

The memory structure 200 can be multidimensional (e.g., 2D or 3D). The memory structure 200 may include one or more array of memory cells including a 3D array. The memory structure 200 may include a monolithic 3D memory structure in which multiple memory levels are formed above (and not in) a single substrate, such as a wafer, with no intervening substrates. The memory structure 200 may include any type of non-volatile memory that is monolithically formed in one or more physical levels of arrays of memory cells having an active area disposed above a silicon substrate. The memory structure 200 may be in a non-volatile memory device having circuitry associated with the operation of the memory cells, whether the associated circuitry is above or within the substrate.

The control circuitry 220 cooperates with the read/write circuits 230 to perform memory operations on the memory structure 200. The control circuitry 220 includes a state machine 221, a storage region 213, an on-chip address decoder 224, a power control/ program voltage module 216, and routing reduction component 150. The state machine 221 provides chip-level control of memory operations. The storage region 213 may be provided, e.g., for operational parameters and software/code. In one embodiment, the state machine 221 is programmable by the software. In other embodiments, the state machine 221 does not use software and is completely implemented in hardware (e.g., electrical circuits).

The on-chip address decoder 224 provides an address interface between that used by the host 243 or a memory controller 244 to the hardware address used by the decoders 240A/240B and 242. The power control module 216 controls the power and voltages supplied to the word lines, select gate lines, bit lines, and source lines during memory operations. It can include drivers for word lines, SGS and SGD transistors and source lines. The sense blocks 250 can include bit line drivers, in one approach. An SGS transistor is a select gate transistor at a source end or source side of a NAND string, and an SGD transistor is a select gate transistor at a drain-end or drain side of a NAND string.

In some implementations, some of the components can be combined. In various designs, one or more of the components (alone or in combination), other than memory structure 126, can be thought of as at least one control circuit which is configured to perform the techniques described herein including the steps of the processes described herein. For example, a control circuit in FIG. 1B may include any one of, or a combination of, control circuitry 220, state machine 221, decoders 224, 240 and 242, power control/program voltage module 216, routing reduction component 150, sense blocks 250, read/write circuits 230, controller 244, and so forth.

The off-chip controller 244 (which in one embodiment is an electrical circuit) may comprise a processor 222c, storage devices (memory) such as ROM 222a and RAM 222b and an error-correction code (ECC) engine 145. The ECC engine 245 can correct a number of read errors.

A memory interface 222d may also be provided. The memory interface 222d, in communication with ROM 222a, RAM 222b, and processor 222c, is an electrical circuit that provides an electrical interface between controller 244 and memory die 212. For example, the memory interface 222d can change the format or timing of signals, provide a buffer, isolate from surges, latch I/O and so forth. The processor 222c can issue commands to the control circuitry 220 (or any other component of the memory die 212) via the memory interface 222d.

A storage device 226a of the memory structure 200 includes code such as a set of instructions, and the processor 222c is operable to execute the set of instructions to provide the functionality described herein. Alternatively or additionally, the processor 222c can access code from the storage device 226a of the memory structure 200, such as a reserved area of memory cells in one or more word lines.

For example, code can be used by the controller 244 to access the memory structure 200, such as for programming, read, and erase operations. The code can include boot code and control code (e.g., a set of instructions). The boot code is software that initializes the controller 244 during a booting or startup process and enables the controller 244 to access the memory structure 200. The code can be used by the controller 244 to control one or more memory structures 200. Upon being powered up, the processor 222c fetches the boot code from the ROM 222a or storage device 226a for execution, and the boot code initializes the system components and loads the control code into the RAM 222b. Once the control code is loaded into the RAM 222b, it is executed by the processor 222c. The control code includes drivers to perform basic tasks such as controlling and allocating memory, prioritizing the processing of instructions, and controlling input and output ports.

Generally, the control code can include instructions to perform the functions described herein including the steps of the flowcharts discussed further below, and provide the voltage waveforms including those discussed further below. A control circuit can be configured to execute the instructions to perform the functions described herein.

In one embodiment, the host 243 is a computing device (e.g., laptop, desktop, smartphone, tablet, digital camera) that includes one or more processors, one or more processor readable storage devices (RAM, ROM, flash memory, hard disk drive, solid state memory) that store processor readable code (e.g., software) for programming the one or more processors to perform the methods described herein. The host 243 may also include additional system memory, one or more input/output interfaces and/or one or more input/output devices in communication with the one or more processors.

Other types of non-volatile memory in addition to NAND flash memory can also be used.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read-only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse or phase change material, and optionally a steering element, such as a diode or transistor. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND string is an example of a set of series-connected transistors comprising memory cells and select gate (SG) transistors.

A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured.

The semiconductor memory elements located within and/or over a substrate may be arranged in two or three dimensions, such as a 2D memory structure or a 3D memory structure.

In a 2D memory structure, the semiconductor memory elements are arranged in a single plane or a single memory device level. Typically, in a 2D memory structure, memory elements are arranged in a plane (e.g., in an x-y direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A 3D memory array is arranged so that memory elements occupy multiple planes or multiple memory device levels, thereby forming a structure in three dimensions (i.e., in the x, y and z directions, where the z direction is substantially perpendicular and the x and y directions are substantially parallel to the major surface of the substrate).

As a non-limiting example, a 3D memory structure may be vertically arranged as a stack of multiple 2D memory device levels. As another non-limiting example, a 3D memory array may be arranged as multiple vertical columns (e.g., columns extending substantially perpendicular to the major surface of the substrate, e.g., in the y direction) with each column having multiple memory elements. The columns may be arranged in a 2D configuration, e.g., in an x-y plane, resulting in a 3D arrangement of memory elements with elements on multiple vertically stacked memory planes. Other configurations of memory elements in three dimensions can also constitute a 3D memory array.

By way of non-limiting example, in a 3D NAND memory array, the memory elements may be coupled together to form a NAND string within a single horizontal (e.g., x-y) memory device level. Alternatively, the memory elements may be coupled together to form a vertical NAND string that traverses across multiple horizontal memory device levels. Other 3D configurations can be envisioned wherein some NAND strings contain memory elements in a single memory level while other strings contain memory elements which span through multiple memory levels. 3D memory arrays may also be designed in a NOR configuration and in a ReRAM configuration.

Typically, in a monolithic 3D memory array, one or more memory device levels are formed above a single substrate. Optionally, the monolithic 3D memory array may also have one or more memory layers at least partially within the single substrate. As a non-limiting example, the substrate may include a semiconductor such as silicon. In a monolithic 3D array, the layers constituting each memory device level of the array are typically formed on the layers of the underlying memory device levels of the array. However, layers of adjacent memory device levels of a monolithic 3D memory array may be shared or have intervening layers between memory device levels.

2D arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic 3D memory arrays. Further, multiple 2D memory arrays or 3D memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

It should be understood that this technology is not limited to the 2D and 3D exemplary structures described, can cover any or all relevant memory structures within the spirit and scope of the technology as described herein.

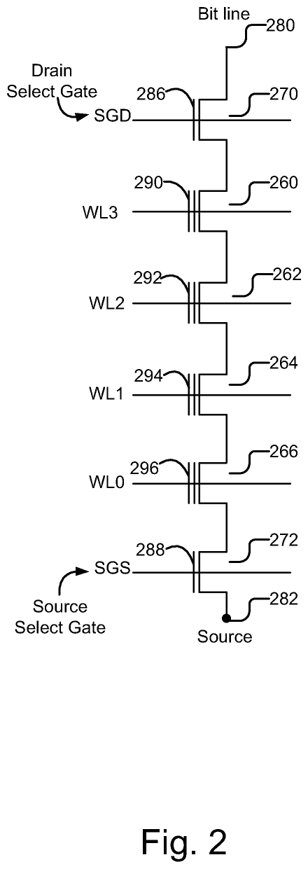

FIG. 2 depicts one embodiment of a NAND string comprising a plurality of storage elements. The NAND string depicted in FIG. 2, in some embodiments, includes four transistors 260, 262, 264, 266 connected in series and located between a first select transistor 270 and a second select transistor 272. In some embodiments, a transistor 260, 262, 264, 266 includes a control gate and a floating gate. A control gate 290, 292, 294, 296, in one embodiment, is connected to, or comprises a portion of, a word line. In a further embodiment, a transistor 260, 262, 264, 266 is a storage element, storage cell, or the like, also referred to as a memory cell. In some embodiments, a storage element may include multiple transistors 260, 262, 264, 266.

The first select transistor 270, in some embodiments, gates/connects the NAND string connection to a bit line 280 via a drain select gate SGD. The second select transistor 272, in certain embodiments, gates/connects the NAND string connection to a source line 282 via a source select gate SGS. The first select transistor 270, in a further embodiment, is controlled by applying a voltage to a corresponding select gate 286. The second select transistor 272, in some embodiments, is controlled by applying a voltage to corresponding select gate 288.

As shown in FIG. 2, the source line 282, in one embodiment, is connected to the sources of each transistor/storage cell 260, 262, 264, 266 in the NAND string. The NAND string, in some embodiments, may include some storage elements 260, 262, 264, 266 that have been programmed and some storage elements 260, 262, 264, 266 that have not been programmed. A NAND string may be formed in a memory hole in a stack of alternating conductive and dielectric layers filled with materials which form memory cells adjacent to the word lines.

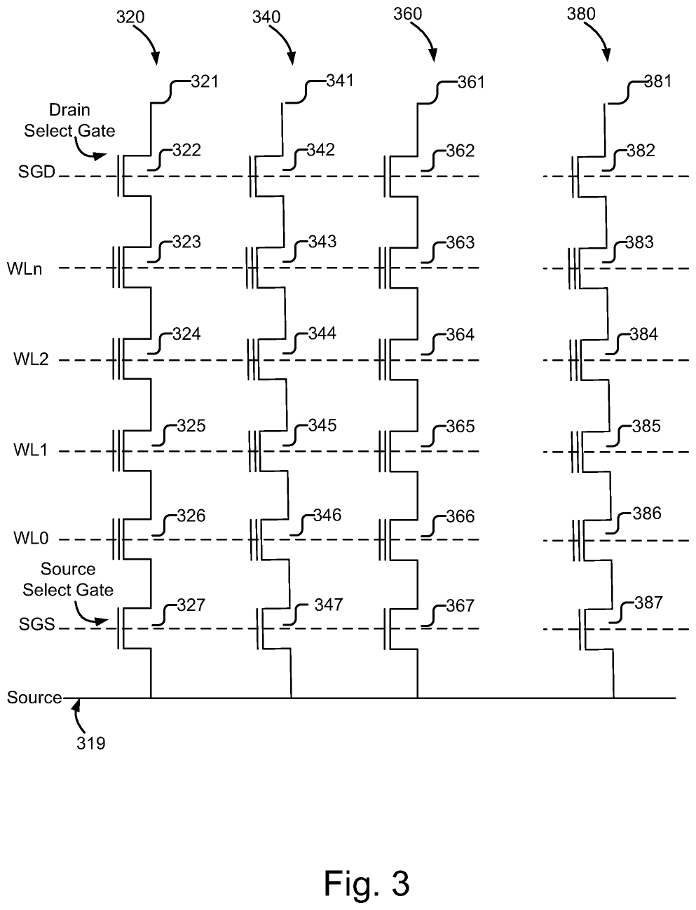

FIG. 3 is a circuit diagram depicting a plurality of NAND strings 320, 340, 360, 380. An architecture for a flash memory system using a NAND structure may include several NAND strings 320, 340, 360, 380. For example, FIG. 3 illustrates NAND strings 320, 340, 360, 380 in a memory structure 200 that includes multiple NAND strings 320, 340, 360, 380. In the depicted embodiment, each NAND string 320, 340, 360, 380 includes drain select transistors 322, 342, 362, 382, source select transistors 327, 347, 367, 387, and storage elements 323-326, 343-346, 363-366, 383-386. While four storage elements 323-326, 343-346, 363-366, 383-386 per NAND string 320, 340, 360, 380 are illustrated for simplicity, some NAND strings 320, 340, 360, 380 can include any number of storage elements, e.g., thirty-two, sixty-four, or the like storage elements. The NAND strings 320, 340, 360, 380 are examples of vertical memory strings which extend upward from a substrate.

NAND strings 320, 340, 360, 380, in one embodiment, are connected to a source line 319 by source select transistors 327, 347, 367, 387. A selection line SGS may be used to control the source side select transistors. The various NAND strings 320, 340, 360, 380, in one embodiment, are connected to bit lines 321, 341, 361, 381 by drain select transistors 322, 342, 362, 382. The drain select transistors 322, 342, 362, 382 may be controlled by a drain select line SGD. In some embodiments, the select lines do not necessarily need to be in common among the NAND strings 320, 340, 360, 380; that is, different select lines can be provided for different NAND strings 320, 340, 360, 380.

As described above, each word line WL0-WLn comprises one or more storage elements 323-383, 324-384, 325-385, 326-386. In the depicted embodiment, each bit line 321, 341, 361, 381 and the respective NAND string 320, 340, 360, 380 comprise the columns of the memory structure 200, storage block, erase block, or the like. The word lines WL0-WLn, in some embodiments, comprise the rows of the memory structure 200, storage block, erase block, or the like. Each word line WL0-WLn, in some embodiments, connects the control gates of each storage element 323-383, 324-384, 325-385, 326-386 in a row. Alternatively, the control gates may be provided by the word lines WL0-WLn themselves. In some embodiments, a word line WLO-WLn may include tens, hundreds, thousands, millions, or the like of storage elements 323-383, 324-384, 325-385, 326-386.

In one embodiment, each storage element 323-326, 343-346, 363-366, 383-386 is configured to store data. For example, when storing one bit of digital data, the range of possible threshold voltages (“VTH”) of each storage element 323-326, 343-346, 363-366, 383-386 may be divided into two ranges which are assigned logical data “1” and “0.” In one example of a NAND type flash memory, the VTH may be negative after the storage elements 323-326, 343-346, 363-366, 383-386 are erased, and defined as logic “1.” In one embodiment, the VTH after a program operation is positive and defined as logic “0.”

When the VTH is negative and a read is attempted, in some embodiments, storage elements 323-326, 343-346, 363-366, 383-386 will turn on to indicate logic “1” is being stored. When the VTH is positive and a read operation is attempted, in a further embodiment, a storage element will not turn on, which indicates that logic “0” is stored. Each storage element 323-383, 324-384, 325-385, 326-386 may also store multiple levels of information, for example, multiple bits of digital data. In such an embodiment, the range of VTH value is divided into the number of levels of data. For example, if four levels of information can be stored in each storage element 323-326, 343-346, 363-366, 383-386, there will be four VTH ranges assigned to the data values “11”, “10”, “01”, and “00.”

In one example of a NAND type memory, the VTH after an erase operation may be negative and defined as “11.” Positive VTH values may be used for the states of “10”, “01”, and “00.” In one embodiment, the specific relationship between the data programmed into the storage elements 323-326, 343-346, 363-366, 383-386 and the threshold voltage ranges of the storage elements 323-326, 343-346, 363-366, 383-386 depends upon the data encoding scheme adopted for the storage elements 323-326, 343-346, 363-366, 383-386.

In some embodiments, temperature compensation used for sensing data on the storage elements 323-326, 343-346, 363-366, 383-386 may be noisy resulting in reduced sensing accuracy.

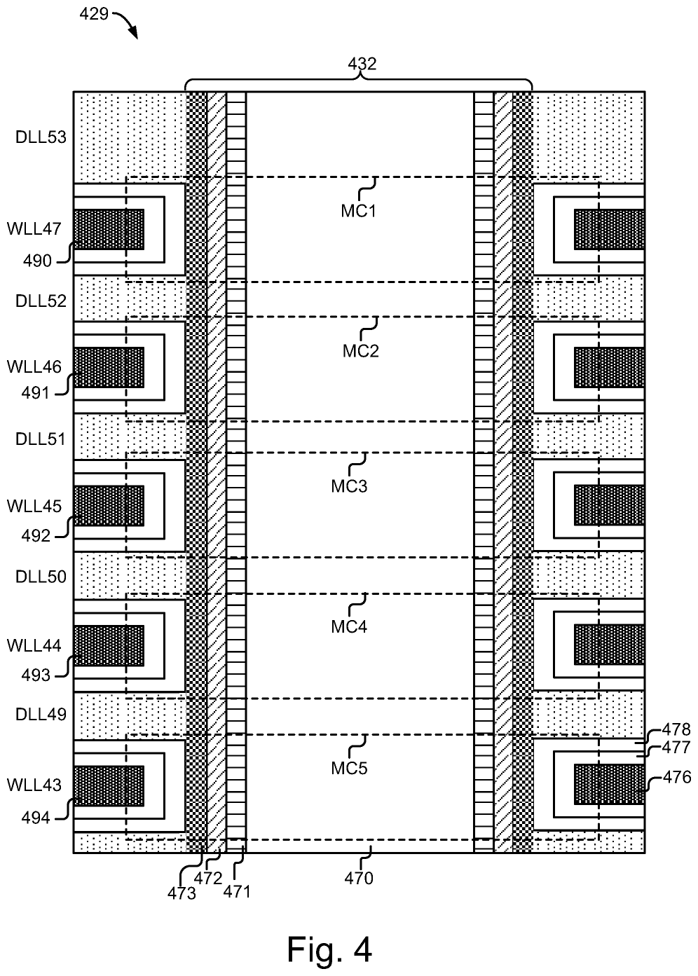

FIG. 4 illustrates one embodiment of a cross-sectional view of a 3D, vertical NAND flash memory structure 429 or string 429. In one embodiment, the vertical column 432 is round and includes four layers; however, in other embodiments more or less than four layers can be included and other shapes can be used (e.g., a “U” shape instead of an “I” shape or the like). In one embodiment, a vertical column 432 includes an inner core layer 470 that is made of a dielectric, such as SiO2. Other materials can also be used. Surrounding inner core 470 is polysilicon channel 471. Materials other than polysilicon can also be used. Note that it is the channel 471 that connects to the bit line. Surrounding channel 471 is a tunneling dielectric 472. In one embodiment, tunneling dielectric 472 has an ONO structure. Surrounding tunneling dielectric 472 is a shared charge trapping layer 473, such as (for example) Silicon Nitride. Other materials and structures can also be used. The technology described herein is not limited to any particular material or structure.

FIG. 4 depicts dielectric layers DLL49, DLL50, DLL51, DLL52, and DLL53, as well as word line layers WLL43, WLL44, WLL45, WLL46, and WLL47. In this example, each of the word line layers includes a word line region 476 surrounded by an aluminum oxide layer 477, which is surrounded by a blocking oxide (SiO2) layer 478. The physical interaction of the word line layers with the vertical column forms the memory cells. Thus, a memory cell, in one embodiment, comprises channel 471, tunneling dielectric 472, charge trapping layer 473 (e.g., shared with other memory cells), blocking oxide layer 478, aluminum oxide layer 477, and word line region 476. In some embodiments, the blocking oxide layer 478 and aluminum oxide layer 477, may be replaced by a single layer of material with insulating properties or by more than 2 layers of different material with insulating properties. Furthermore, the materials used are not limited to silicon dioxide (SiO2) or aluminum oxide. For example, word line layer WLL47 and a portion of vertical column 432 comprise a memory cell MC1. Word line layer WLL46 and a portion of vertical column 432 comprise a memory cell MC2. Word line layer WLL45 and a portion of vertical column 432 comprise a memory cell MC3. Word line layer WLL44 and a portion of vertical column 432 comprise a memory cell MC4. Word line layer WLL43 and a portion of vertical column 432 comprise a memory cell MC5. In other architectures, a memory cell may have a different structure; however, the memory cell would still be the storage unit.

When a memory cell is programmed, electrons are stored in a portion of charge trapping layer 473 which is associated with the memory cell. These electrons are drawn into charge trapping layer 473 from channel 471, through tunneling dielectric 472, in response to an appropriate voltage on word line region 476. The threshold voltage (Vth) of a memory cell is increased in proportion to the amount of stored charge. In one embodiment, programming is achieved through Fowler-Nordheim tunneling of the electrons into the charge trapping layer. During an erase operation, the electrons return to the channel or holes are injected into charge trapping layer 473 to recombine with electrons. In one embodiment, erasing is achieved using hole injection into charge trapping layer 473 via a physical mechanism such as gate induced drain leakage (GIDL).

Storage cells in the same location or position in different memory structures 429 (e.g., different NAND strings 429) on different bit lines, in certain embodiments, may be on the same word line. Each word line may store one page of data, such as when 1-bit of data is stored per cell (SLC); two pages of data, such as when 2-bits of data are stored per cell (MLC); three pages of data, such as when 3-bits of data are stored per cell (TLC); four pages of data, such as when 4-bits of data are stored per cell (QLC); or another number of pages of data.

In the depicted embodiment, a vertical, 3D NAND flash memory structure 429 comprises an “I” shaped memory structure 429. In other embodiments, a vertical, 3D NAND flash memory structure 429 may comprise a “U” shaped structure, or may have another vertical and/or stacked architecture. In certain embodiments, four sets of strings 429 (e.g., four sets of 48 word lines, or another predefined number of word lines) may form a block (e.g., erase block), while in other embodiments, fewer or more than four sets of strings 429 may form a block. As may be appreciated, any suitable number of storage cells may be part of a single string 429. In one embodiment, a single string 429 includes 48 storage cells.

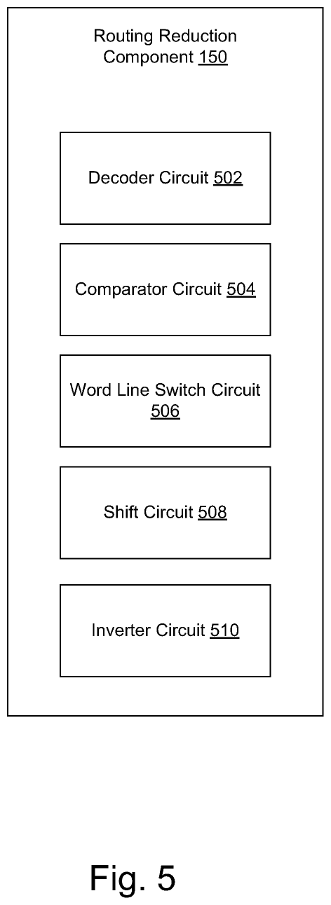

FIG. 5 depicts one embodiment of a routing reduction component 150. The routing reduction component 150 may be substantially similar to the routing reduction component 150 described above with regard to FIGS. 1A and/or 1B. In general, as described above, the routing reduction component 150 senses bad block data from a latch circuit indicating a condition of a first memory block at one end of the array of memory cells. The routing reduction component 150 generates a block selection signal for selecting the first memory block based on the condition of the first memory block. The routing reduction component 150 also couples the sensed bad block data onto a bus. The bus may be a block decoder bus that is common to other (e.g., some, all) latch circuits storing bad block data for other memory blocks. The routing reduction component 150 compares the bad block data against a reference value, sets a bad block flag based on the comparison, and routes the bad block flag across the array of memory cells to the other end (e.g., opposite end) of the array. If the bad block flag received at the other end of the array indicates that the first memory block is operational (e.g., good, non-defective), then another block selection signal for selecting a second memory block is generated at the other end. Thus, the block selection signal for selecting the first and the second memory block are shared via the bad block flag. Accordingly, the routing reduction component 150 may reduce the routing of a number of block selection signals across the array of memory cells to routing one, single, bad block flag, for example. In certain embodiments, as a result of reducing the number of routing signals that are routed across the array, power may be reduced and performance may be improved. This may be at least because the routing line carrying the bad block data does not need to be charged to as high of a voltage. In the depicted embodiment, the routing reduction component 150 includes a decoder circuit 502, a comparator circuit 504, a word line switch circuit 506, a shift circuit 508, and an inverter circuit 510.

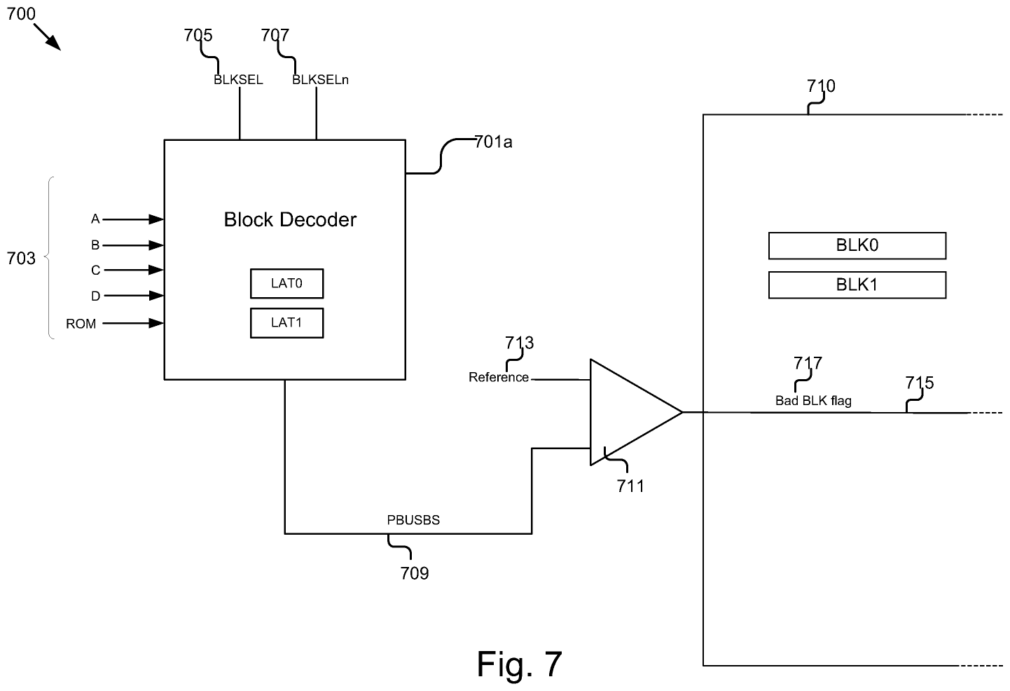

In some embodiments, the decoder circuit 502 performs bad block sensing to determine whether one or more memory blocks are defective. As shown further in FIG. 7, for example, the decoder circuit 502 senses latch data or block data stored in one or more latch circuits LAT0 and LAT1 in a block decoder 701a (see FIG. 7). A latch circuit, such as LAT0, LAT1, etc., may be a block latch that stores block data (e.g., good block data, bad block data, etc.) which indicates a condition of a corresponding memory block.

As used herein, “block data” means any signal, logic level, data, data value, data latch configuration, memory cell state, logic unit state that represents the condition of a memory block. Examples, of block data include, but are not limited to, a logical “1” data value, a state of a flip-flop, and the like. Accordingly, “good block data,” as used herein, is block data that signals/indicates that the memory block is in a state and/or condition such that it can be used to service storage operations. In other words, good block data indicates that the memory block is operational, non-defective, functional, usable, reliable, good, or the like. Conversely, “bad block data,” as used herein, is block data that signals/indicates that the memory block is not in a state and/or condition such that it can be used to service storage operations. In other words, bad block data indicates that the memory block is not operational, defective, non-functional, unusable, unreliable, bad, or the like.

The condition of a memory block may be defined as good (e.g., operational, non-defective, functional, usable, reliable) or bad (e.g., non-operational, defective, non-functional, unusable, unreliable). The value or voltage of the bad block data in the latch circuit LAT0 may represent the condition of the memory block. For example, the latch circuit may hold a logic low-level data when the corresponding block is bad and hold a logic high-level data when the corresponding block is good. The decoder circuit 502 allows activation of block selection signals for selecting a memory block in response to the latch data indicating that the memory block is good. The decoder circuit 502 inhibits the activation of the block selection signals for selecting the memory block in response to the latch data indicating that the memory block is bad. The decoder circuit 502 also reads out the latch data from the latch circuit onto a bus. See FIG. 7. The bus may comprise a block decoder bus 709 common to a set of block decoders stacked on top of each other on either side of the array of memory cells. In one approach, the bus may be coupled to a routing line for communicating the bad block information (e.g., bad block flag) from a first block decoder circuit on one side of the array of memory cells to second block decoder circuit on the opposite side of the array. In some example embodiments, the first block decoder circuit and the second block decoder circuit may share four memory blocks, and each of the first block decoder circuit and the second block decoder circuit may include two latch circuits, as shown in FIG. 7, although other suitable variations may also apply.

In some embodiments, the decoder circuit 502 receives a bad block flag from a first end or side of the array of memory cells, determines a condition of a first memory block on the first end or side based on the bad block flag, and generates block selection signals for selecting a second memory block on a second end or side of the array of memory blocks. For example, the decoder circuit 502 may allow the activation of block selection signals for selecting a second memory block on a second end or side of the array of memory cells if the bad block flag received from the first end or side of the array of memory cells is set low. A logic low level bad block flag indicates that the first memory block is good. In another example, the decoder circuit 502 may inhibit the activation of block selection signals for selecting a second memory block on the second end or side of the array of memory cells if the bad block flag is set high. A logic high level bad block flag indicates that the first memory block is bad. The first memory block and the second memory block are part of a unit of four memory blocks sharing the same block selection signals.

In some embodiments, the decoder circuit 502 generates the block selection signals for selecting and/or unselecting a memory block. The block selection signals may comprise gate voltages for two or more word line switches and select gate line switches used for selecting or unselecting a memory block. The two or more of the word line switches and select gate line switches on opposite sides of an array of memory elements may be referred to as a transfer circuit. The transfer circuit may supply voltages to the word lines and select gate lines of a memory block. In certain embodiments, the gate voltages include a block select gate voltage (e.g., BLKSEL) and an inverse polarity block select gate voltage (e.g., BLKSELn). As used herein, an inverse polarity voltage may mean that if one voltage is a logic high, the other voltage is a logic low. For example, if BLKSEL gate voltage is a logic high, then BLKSELn gate voltage may be a logic low. As another example, if the BLKSELn gate voltage is a logic high, then BLKSEL gate voltage may be a logic low. The decoder circuit 502 may determine the polarity of BLKSEL and BLKSELn gate voltages for selecting or unselecting a memory block. For selecting a memory block, BLKSEL gate voltage is a logic high and BLKSELn gate voltage is a logic low. For unselecting a memory block, BLKSEL gate voltage is a logic low and BLKSELn gate voltage is a logic high.

In some embodiments, the two or more of the word line switches and select gate line switches may be on opposite sides of an array of memory elements (e.g., the memory structure 200) and may be used for coupling word line voltages to word lines and for coupling select gate voltages to select gate lines. In certain embodiments, the two or more select gate line switches control the select gate drain transistors. The gate voltages may be generated in any suitable manner, such as by using a level shifter, an inverter, a power source, and so forth as described herein. In some embodiments, the gate voltages (e.g., BLKSEL) may be approximately 0 volts to turn off (e.g., inhibit, deactivate) each of the two or more word line switches. In certain embodiments, the gate voltages (e.g., BLKSEL) may be approximately 25 volts (e.g., in a range between 20 volts and 35 volts) to turn on (e.g., enable, activate) each of the two or more word line switches. For example, in response to a word line switch being turned on, voltage from a control gate may be passed through the word line switch to a word line. In response to a word line switch being turned off, voltage from the control gate is not passed through the word line switch and the word line is left floating. In some embodiments, the gate voltages (e.g., BLKSELn) for two or more select gate line switches may be approximately 0 volts to turn off (e.g., inhibit, deactivate) a select gate line switch used to control a select gate drain transistor. In some embodiments, the gate voltages (e.g., BLKSELn) may be approximately 2.5 volts (e.g., in a range between 1.5 volts and 3.5 volts) to turn on (e.g., enable, activate) a select gate line switch used to control a select gate drain transistor. However, it should be understood that in further embodiments other voltage levels may apply. In response to a select gate line switch being turned on, voltage from VSS may be passed through the select gate line switch to a select gate drain transistor.

In some embodiments, the comparator circuit 504 sets the bad block flag based on the latch data or block data received on the bus and routes the bad block flag on a routing line across the array of memory cells from one side to an opposite side. The comparator circuit 504 may receive the latch data from the bus and compare the latch data against a reference value for setting the bad block flag. In such embodiments, the bad block flag may be set to a high level to indicate a bad memory block and set to a comparatively low level to indicate a good memory block. For example, the comparator circuit 504 may set the bad block flag to a logically low value if the value of the latch data is greater than the reference value. In another example, the comparator circuit 504 sets the bad block flag to a logically high value if the value of the latch data is less than the reference value.

In some embodiments, the gate voltages generated for two or more word line switches and select gate line switches by the decoder circuit 502 may be based on the bad block flag routed on the routing line extending across the array of memory elements (e.g., the memory structure 200). In such embodiments, a voltage of the routing line carrying the bad block flag may be about 2 volts, although other values may apply in other embodiments. By reducing a voltage carried on the routing line, interference with other routing lines carrying other signals (e.g., bit line voltages) may be reduced and power consumption may be improved. Furthermore, by reducing the voltage carried on the routing line a performance speed may be increased because it may be faster to charge the routing line to a lower voltage than to a higher voltage. Moreover, using only the bad block flag sent on the routing line to generate the gate voltages for word line switches and select gate line switches on either side of the array of memory elements, space may be reduced because only one routing line is used instead of two or more. This reduced space may also improve routing for other design blocks and power distribution.

In some embodiments, the word line switch circuit 506 may supply gate voltages to two or more word line switches. The word line switch circuit 506 may supply the gate voltages to the two or more word line switches using routing circuitry that directly electronically couples the decoder circuit 502 to gates of the two or more word line switches. In some embodiments, the word line switch circuit 506 may supply gate voltages to two or more select gate line switches. The word line switch circuit 506 may supply the gate voltages to the two or more select gate line switches using routing circuitry that directly electronically couples the decoder circuit 502 that generates the gate voltages to the two or more select gate line switches.

In some embodiments, the shift circuit 508 may be configured to increase a voltage of a block selection signal in order to generate a gate voltage for the transfer circuit. For example, in certain embodiments, the shift circuit 508 may be configured to receive the block selection signal generated by the decoder circuit 502 for a selected block, increase the voltage of the block selection signal, and produce the gate voltage (e.g., BLKSEL). BLKSEL may have a voltage value ranging between 20 volts and 35 volts, although other values could apply depending on the configuration.

In some embodiments, the inverter circuit 510 may be configured to invert (e.g., invert a polarity, invert from a logic high to a logic low, invert from a logic low to a logic high) a voltage of a block selection signal generated by the decoder circuit 502 to produce gate voltages. In some embodiments, the shift circuit 508 may be configured to increase the inverted voltage from the inverter circuit 510 and produce the gate voltages in response to the inverted voltage indicating a logic high value.

FIG. 6 depicts an example circuit 600 for providing voltages to a block of memory cells. In this example, a transfer circuit 601a provides voltages to word lines and select gate lines of a block 603 on one end of an array of memory cells. The block 603 could be part of a set of blocks in a plane. One or more other transfer circuits for providing voltages to word lines and select gate lines of other block(s) in the set of blocks on the other end (e.g., opposite end) of the memory cells may be included. In a frequent use case, operations, e.g., program, read or erase, may be performed on one selected block at a time. The word lines may connect to the memory cells and select gate lines may connect to SGD (drain-side select gate) and SGS (source-side select gate) transistors in the block 603. The transfer circuit 601 may include word line switches and select gate line switches that receive the gate voltages BLKSEL 605 and BLKSELn 607 for selecting or unselecting the block 603. As described above, BLKSEL 605 may be set high and BLKSELn 607 may be set comparatively low for a selected block 603. BLKSEL 605 may be set low and BLKSELn 607 may be set comparatively high for an unselected block 603. As depicted in FIG. 6, BLKSEL 605 is the gate voltage of the word line switch 609. When BLKSEL 605 is high (e.g., about 25 volts) for the selected block 603, the word line WL0 611 may receive a word line voltage (e.g., about 20 volts) from a voltage source. When BLKSEL 605 is set to a comparatively low level (e.g., about 0 volts) for the unselected block 603, the word line WL0 611 may be left floating.

In some embodiments, BLKSELn 607 is the gate voltage of select gate line switch 613b. The select gate line switches 613a and 613b form a multiplexer circuit for passing select gate voltage on the select gate line SGD 615. One terminal of the select gate line switch 613b may be provided with a low voltage source (labeled as VSS, which could be ground). When BLKSELn is set to a high level (e.g., about 2.5 volts) for the unselected block 603, VSS may be passed onto the SGD 615 to cut off the block 603. This stops the flow of current in the bit lines of the unselected block 603. When BLKSELn is set to a comparatively low level (e.g., about 0 volts) for the selected block 603, VSGD may be passed onto to the SGD 615 to turn on the select gate transistor in the block 603.

FIG. 7 depicts a schematic block diagram of a configuration 700 illustrating one embodiment for routing a bad block flag 717. As depicted in FIG. 7, the bad block flag 717 is routed from one end of an array 710 of memory cells to an opposite end. The block decoder 701a is provided for two memory blocks at one end of the array 710. At the opposite end, there may be another block decoder 701b (not shown) provided for two other memory blocks. The pair of block decoders 701a and 701b together manage the aggregate set of four memory blocks. The set of four blocks share the same block selection signals 705 and 707. The pair of block decoders 701a and 701b independently generate the same block selection signals 705 and 707 on opposite ends of the array 710 using the bad block flag 717. The block decoder 701a stores bad block information for the two memory blocks in latch circuits LAT0 and LAT1. For example, the latch circuit LAT0 stores good block data or bad block data that indicates whether a corresponding block BLK0 associated with the block decoder 701a is good or bad. Block BLK0 may be considered bad when there is a die short or word line short in the block BLK0 and the block data in the latch circuit LAT0 may be set low accordingly, for example. When the block decoder 701a receives block address signals 703 selecting the set of four memory blocks, the block decoder 701a is configured to determine the block selection signals 705 and 707 based on the bad block data stored in latch circuits LAT0 and LAT1 for two memory blocks and share the bad block data stored in latch circuits LAT0 and LAT1 for two memory blocks with the block decoder 701b on the opposite side of the array 710. The block decoder 701a reads out the bad block data from one or more of the latch circuits LAT0 and LAT1 onto the decoder bus PBUSBS 709. A comparator circuit 711 compares the bad block data on the decoder bus PBUSBS 709 against a reference voltage 713. The comparator circuit 711 sets a bad block flag 717 based on a result of the comparison and routes the bad block flag 717 on a routing line 715 across the array 710 of memory cells. The routing line 715 may extend between the block decoder 701a and block decoder 701b. Although FIG. 7 depicts a single instance of block decoder 701a as an example, there may be other block decoders stacked on top of block decoder 701a. As such, the decoder bus PBUSBS 709 may be coupled to other block decoders for receiving bad block data.

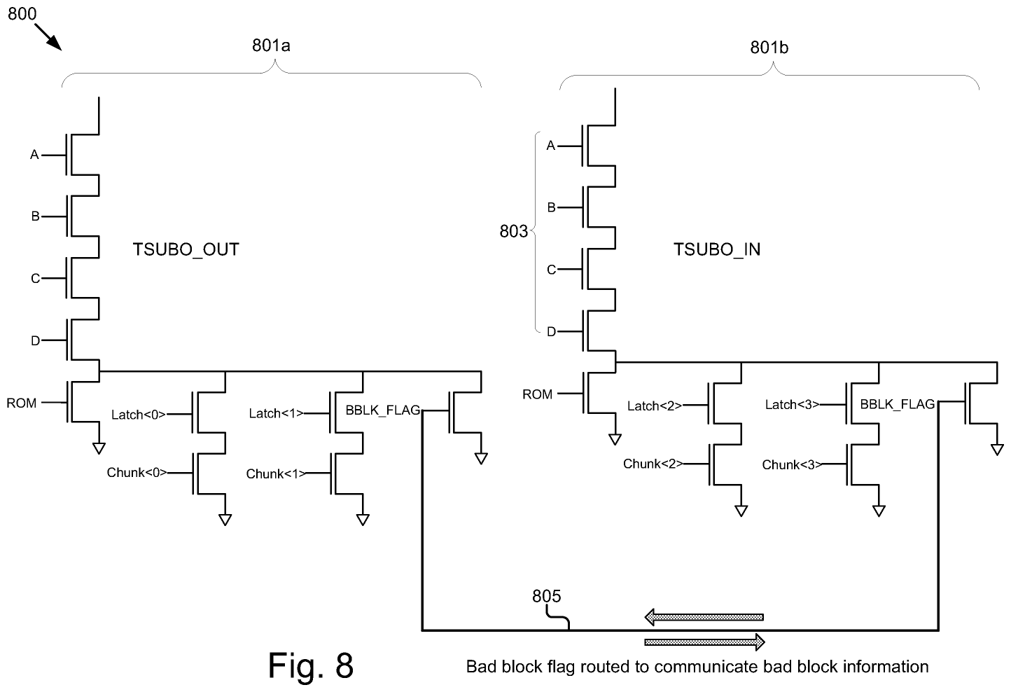

FIG. 8 depicts an example circuit diagram illustrating one embodiment of a circuit 800 for routing a bad block flag between block decoders on opposite sides of an array of memory cells. The circuit 800 depicts a simplified example configuration for routing a bad block flag. The circuit 800 includes a pair of block decoders 801a and 801b, each on an opposite end of the array of memory cells. The pair of block decoders 801a and 801b together manage a chunk set or aggregate set of memory blocks. For example, a chunk set may include four memory blocks (chunk<0>, chunk<1>, chunk<2>, and chunk<3>). Block selection signals BLKSEL and BLKSELn are shared by the four memory blocks. Each of the block decoders 801a and 801b have two latches for storing bad block information corresponding to two blocks. The block decoders 801a and 801b decode the block address signals 803 and determine that one of the four memory blocks is selected for a memory operation. For example, if block 2 (chunk<2>) is selected for a memory operation, the block decoder 801b may be aware that the condition of the block 2 is good from latch<2> and set BLKSEL high and BLKSELn low, for example. However, block decoder 801a may not be aware of the condition of the block 2. As such, the block decoder 801a may also not be able to determine whether to generate BLKSEL and BLKSELn for block 0 (chunk<0>) and block 1 (chunk<1>). To remedy this, the block decoder 801b reads out the bad block data for block 2 from Latch<2> onto the bad block flag BBLK_FLAG and routes BBLK_FLAG routed across the array of memory cells on routing line 805 to the block decoder 801a. If the BBLK_FLAG indicates that block 2 is good, then the block decoder 801a may determine to set BLKSEL high and BLKSELn low, for example. The block decoders 801a and 801b cooperate with each other to determine a generation of same block selection signals on the opposite ends of the array of memory cells. The block decoder 801a/801b may route the BBLK_FLAG on the routing line 805 to communicate the bad block information to the other block decoder 801a/801b accordingly.

The bad block flag BBLK_FLAG can control whether memory blocks of an aggregate set on opposite ends of the array of memory cells get selected (or unselected) for a memory operation. In some embodiments, if the bad block flag BBLK_FLAG is set, the memory blocks (e.g., neither the first memory block nor the second memory block) of the aggregate set on the opposite ends of the array are not activated by the block decoders 801a and 801b for a memory operation. In further embodiments, if the bad block flag BBLK_FLAG is not set, then the memory blocks (e.g., the first memory block, the second memory block, etc.) of the aggregate set on the opposite ends of the array are activated by the block decoders 801a and 801b for a memory operation.

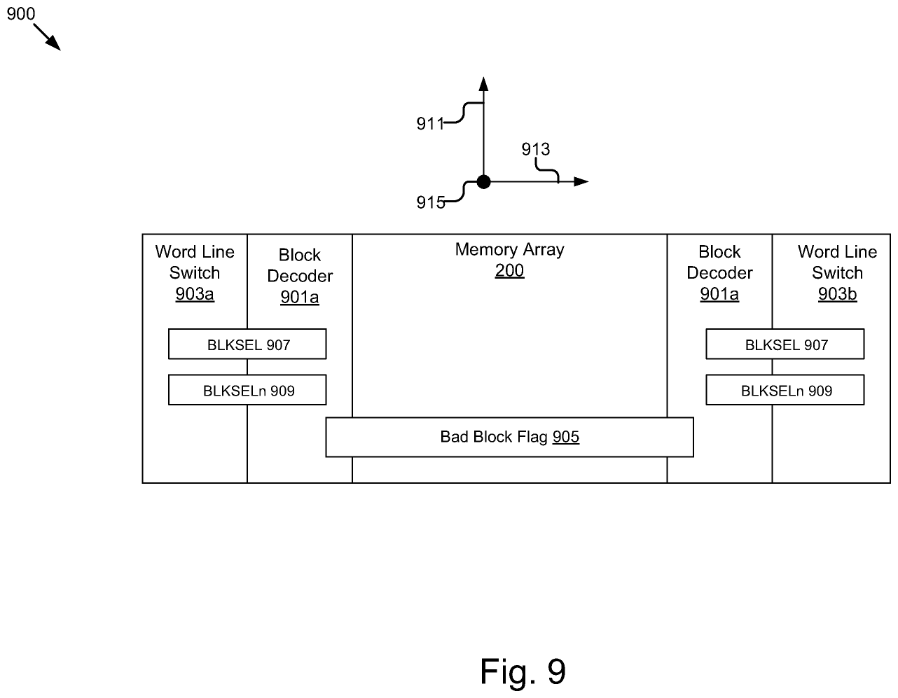

FIG. 9 is a schematic block diagram illustrating a further embodiment of a system 900 for routing a bad block flag. The system 900 includes the memory array 200 (e.g., an array of storage elements), a first block decoder circuit 901a on one side of the memory array 200, a second block decoder 901b on a different (e.g., opposite) side of the memory array 200, a bad block flag routing line 905, a first word line switch 903a, and a second word line switch 903b. The bad block flag routing line 905 may extend along an x-axis 913 over the first block decoder circuit 901a and the second block decoder 901b. In one implementation, the first block decoder circuit 901a, the second block decoder 901b, and the bad block flag routing line 905 may be in a different plane below the memory array 200 (e.g., CMOS under array configuration). Other configurations, such as CMOS next to array (CnA) and CMOS bonded above array (CbA), may also apply. The bad block flag routing line 905 may be in a metal layer (M1 metal layer) or another conductive layer between the different/opposite sides of the memory array 200. A y-axis 911 and a z-axis 915 are shown for perspective relative to the x-axis 913. The z-axis 915 extends into the page. In one embodiment, the first block decoder circuit 901a is coupled to one end of the bad block flag routing line 905 and the second block decoder 901b is coupled to an opposite end of the bad block flag routing line 905. The first and second block decoder circuits 901a and 901b may operate in a similar manner to the decoder circuit 502. In some embodiments, block select gate voltages BLKSEL 907 and BLKSELn 909 may be supplied to word line switch gates and select line switch gates of the first and second word line switches 903a and 903b based on bad block flag on the bad block flag routing line 905.

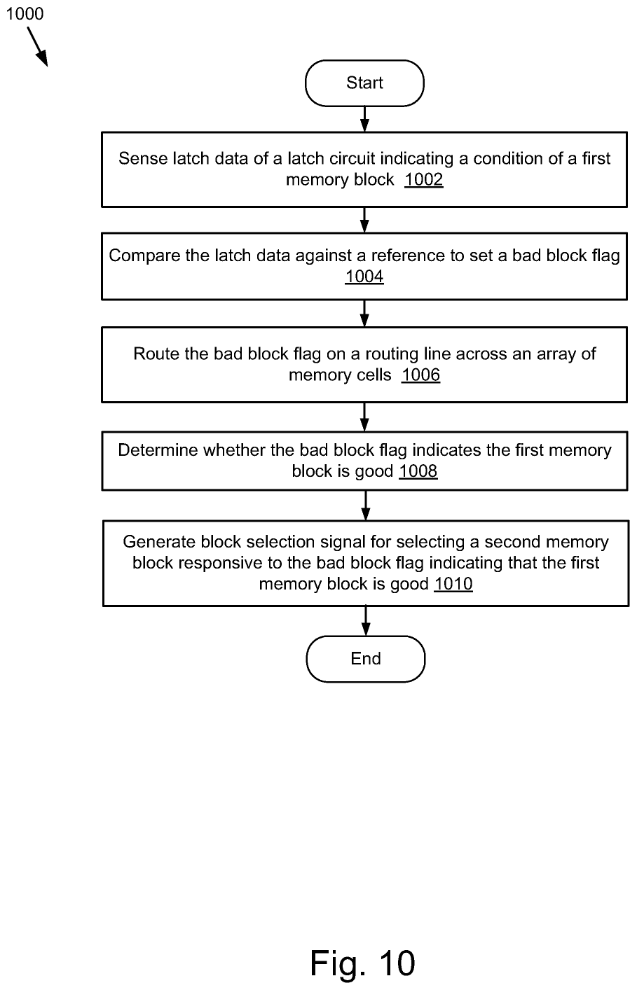

FIG. 10 depicts a flowchart of an example process 1000 for routing a bad block flag which advantageously reduces the number of routing signals across the array of memory cells. Step 1002 begins by the decoder circuit 502 sensing latch data of a latch circuit indicating a condition of a first memory block. For example, the latch circuit stores data that indicates whether the memory block is good or bad. Step 1004 includes the comparator circuit 504 comparing the latch data against a reference to set a bad block flag. For example, if the bad block flag is set high, then it is indicative of a bad block. Step 1006 continues with the comparator circuit 504 routing the bad block flag on a routing line across an array of memory cells. For example, the routing line may be an upper metal layer (M1 layer) and extends between block decoders on either side of the array of memory cells. Step 1008 includes the decoder circuit 502 determining whether the bad block flag is indicating that the first memory block is good. Step 1010 includes the decoder circuit 502 generating block selection signals for selecting a second memory block responsive to the bad block flag indicating that the first memory block is good.

A means for routing a bad block flag across an array of memory elements, generating block selection signals based on the bad block flag on each end of the array of memory elements, and supplying the block selection signals to a plurality of transfer circuits, in some embodiments, may include one or more of a routing component 150, a non-volatile memory device 120, a non-volatile memory medium controller 126, a non-volatile memory device interface 139, a host computing device 110, a device driver, a controller (e.g., a device driver, or the like) executing on a host computing device 110, a processor 111, an FPGA, an ASIC, other logic hardware, and/or other executable code stored on a computer-readable storage medium.

The foregoing detailed description of the invention has been presented for purposes of illustration and description. It is not intended to be exhaustive or to limit the invention to the precise form disclosed. Many modifications and variations are possible in light of the above teachings. The described embodiments were chosen in order to best explain the principles of the invention and its practical application, to thereby enable others skilled in the art to best utilize the invention in various embodiments and with various modifications as are suited to the particular use contemplated. It is intended that the scope of the invention be defined by the claims appended hereto.

What is claimed is:

1. An apparatus comprising:
a first block decoder circuit configured to determine first latch data of a first latch circuit and read out the first latch data onto a bus, the first latch circuit storing the first latch data indicating a condition of a first memory block; and
a comparator circuit configured to receive the first latch data from the bus, set a block flag based on the first latch data and send the block flag on a routing line to a second block decoder circuit.

2. The apparatus of claim 1, further comprising:
the second block decoder circuit configured to receive the block flag from the routing line and determine whether the block flag indicates that the first memory block is defective.

3. The apparatus of claim 2, wherein:
responsive to the block flag indicating that the first memory block is defective, the second block decoder circuit is configured to inhibit an activation of a block selection signal for selecting a second memory block.

4. The apparatus of claim 2, wherein:
responsive to the block flag indicating that the first memory block is non-defective, the second block decoder circuit is configured to allow an activation of a block selection signal for selecting a second memory block.

5. The apparatus of claim 2, wherein:
the second block decoder circuit is configured to determine second latch data of a second latch circuit, the second latch circuit storing the second latch data indicating a condition of a second memory block.

6. The apparatus of claim 5, wherein the first block decoder circuit and the second block decoder circuit are on opposite sides of an array of memory elements.

7. The apparatus of claim 5, wherein the first memory block and the second memory block comprise a unit of memory blocks.

8. The apparatus of claim 7, wherein the first block decoder circuit and the second block decoder circuit determine an activation of a block selection signal shared by the unit of memory blocks.

9. The apparatus of claim 8, wherein a plurality of transfer circuits are on opposite sides of an array of memory elements configured to receive the block selection signal.

10. The apparatus of claim 1, wherein the routing line carrying the block flag is an upper metal layer.

11. A system comprising:
a control circuit coupled to an array of storage elements, the control circuit comprising:
a first block decoder circuit configured to sense bad block data of a first latch circuit corresponding to a first memory block and couple the bad block data onto a bus;
a comparator circuit configured to compare a value of the bad block data from the bus against a reference value, set a bad block flag based on the comparison and route the bad block flag on a routing line across the array of storage elements; and
a second block decoder circuit configured to receive the bad block flag from the routing line, determine a condition of the first memory block based on the bad block flag and generate a block selection signal for selecting a second memory block based on the condition of the first memory block.

12. The system of claim 11, wherein:
the comparator circuit is configured to set the bad block flag to a logic low value if the value of the bad block data is greater than the reference value.

13. The system of claim 12, wherein:
the second block decoder circuit is configured to determine that the condition of the first memory block is good in response to the logic low value of the bad block flag and allow the generation of the block selection signal for selecting the second memory block.

14. The system of claim 13, further comprising:
a shift circuit configured to increase a voltage of the block selection signal to generate a gate voltage for a transfer circuit associated with the second memory block.

15. The system of claim 11, wherein:
the comparator circuit is configured to set the bad block flag to a logic high value if the value of the bad block data is less than the reference value.

16. The system of claim 15, wherein:
the second block decoder circuit is configured to determine that the condition of the first memory block is bad in response to the logic high value of the bad block flag and inhibit the generation of the block selection signal for selecting the second memory block.

17. An apparatus comprising:
a control circuit placed under an array of storage elements, the control circuit comprising:
a first block decoder circuit, at a first end of the array of storage elements, configured to sense a voltage of bad block data stored by a first latch circuit for a first memory block and transfer the sensed voltage onto a bus;
a comparator circuit configured to compare the sensed voltage against a reference voltage, set a bad block flag based on the comparison, and transmit the bad block flag to a second block decoder circuit on a routing line extending between the first block decoder circuit and the second block decoder circuit; and
the second block decoder circuit, at a second end of the array of storage elements opposite to the first end, configured to determine that the first memory block is operational based on the bad block flag and generate a block selection signal for selecting a second memory block responsive to the bad block flag indicating that the first memory block is operational.

18. The apparatus of claim 17, wherein:
the second block decoder circuit is configured to inhibit generating the block selection signal responsive to the bad block flag indicating the first memory block is non-operational.

19. The apparatus of claim 17, further comprising:
an inverter circuit configured to invert a polarity of the block selection signal to generate an inverse polarity block selection signal; and
a shift circuit configured to increase a voltage of the block selection signal to generate a gate voltage for a transfer circuit associated with the second memory block.

20. The apparatus of claim 19, wherein a voltage of the routing line transferring the bad block flag is about 2 volts and the gate voltage is about 30 volts.
